(19) United States
(12) Patent Application Publication
(10) Pub. No.: US 2022/0417664 A1
(43) Pub. Date: Dec. 29, 2022

(54) MICRO-SPEAKER AND DAMPER FOR MICRO-SPEAKERS

(71) Applicant: Vanson Electronics (Nanhai) Co., Ltd., Foshan City (CN)

(72) Inventors: Ching-Shan Hsu, Taipei City (TW); Hao-Chien Hsu, Taipei City (TW)

(73) Assignee: Vanson Electronics (Nanhai) Co., Ltd., Foshan City (CN)

(21) Appl. No.: 17/380,005

(22) Filed: Jul. 19, 2021

(30) Foreign Application Priority Data
Jun. 25, 2021 (CN) 202110711697.3

(51) Int. Cl. H04R 9/04; H05K 1/02; H04R 9/02

(52) U.S. Cl. CPC H04R 9/043; H05K 1/0277; H04R 9/025; H05K 2201/10083

(57) ABSTRACT

A micro-speaker includes a frame body, a diaphragm on the frame body, a magnetic structure and a voice coil in the frame body. An upper end of the voice coil is fixed to the diaphragm. The magnetic structure is arranged under the voice coil. A voice coil balancing system is provided in the frame body, which is composed of two symmetrically arranged dampers, which are respectively arranged under two ends of a long axis of the voice coil and fixed with glue. Each of the dampers is made of a flexible circuit board, including a first end, a second end and a cantilever connecting the first end and the second end. A ratio of a length L of the cantilever to a distribution distance D of the cantilever is between 2-15.

### BACKGROUND OF THE INVENTION

### 1. Field of the Invention

The invention relates to the technical field of loudspeaker, in particular to a micro-speaker and a damper for micro-speakers.

### 2. Description of the Prior Art

A loudspeaker is a kind of transducer element that converts electrical signals into acoustic signals, and is an important acoustic component in electronic products. The speaker module usually includes a frame and a magnetic system and a vibration system disposed within the frame. The vibration system includes a diaphragm and a voice coil arranged under the diaphragm. The voice coil drives the diaphragm to produce sound under the vibration of the magnetic system.

With the high pursuit of portability of electronic products, reducing the size is a necessary goal when updating various micro-speaker products, but the reduction in volume means that the volume of the magnet of the micro-speaker must be reduced at the same time, resulting in a decrease in output of the sound. Increasing the power may compensate the decrease in output of the sound caused by the smaller magnet. However, the micro-speaker faces the risk of tearing the voice coil lead due to excessive amplitude.

### SUMMARY OF THE INVENTION

It is one objective of the present invention to provide a micro-speaker and a damper for the micro-speaker, so as to solve the above-mentioned problems of the prior art.

In order to achieve the above objectives, the present disclosure provides the following technical solutions:

A micro-speaker includes a frame body, a diaphragm arranged on the frame body, a magnetic structure and a voice coil arranged in the frame body. An upper end of the voice coil is fixed to the diaphragm. The magnetic structure is arranged under the voice coil. A voice coil balancing system is provided in the frame body, which is composed of two symmetrically arranged dampers, which are respectively arranged under two opposite ends of a long axis of the voice coil and fixed with glue. Each of the dampers is made of a flexible circuit board, including a first end, a second end and a cantilever connecting the first end and the second end, and wherein a ratio of a length L of the cantilever to a distribution distance D of the cantilever is between 2-15.

According to some embodiments, the damper has a left-right symmetrical structure.

According to some embodiments, the cantilever has no copper layer on a front surface of the damper and a surface of the substrate is exposed.

According to some embodiments, the substrate is made of a polymer material.

According to some embodiments, a voice coil lead is fixed to a welding part of the first end on a front surface of the damper by using electronic spot welding, which is connected to a circuit on a bottom surface of the damper through a via hole, which is electrically connected to a connection terminal on the bottom surface of the second end.

According to some embodiments, an external signal wire is welded to the connection terminal on the bottom surface of the second end.

According to some embodiments, a width of the cantilever is 0.45 mm.

According to some embodiments, the diaphragm is arranged in a slender shape, and wherein a size of the diaphragm in a length direction is larger than a size in a width direction.

According to some embodiments, the frame body has an opening that matches a shape of the diaphragm, and the diaphragm is connected to the frame by a ring-shaped surround to seal the opening.

According to some embodiments, the magnetic structure includes a main magnetic portion, a side magnetic portion around an outer periphery of the main magnetic portion, and a yoke under the side magnetic portion and the side magnetic portion, and wherein a gap is located between the main magnetic portion and the side magnetic portion, and the voice coil is disposed around the outer periphery of the main magnetic portion and installed in the gap.

According to some embodiments, washers for magnetic conduction are provided on the main magnetic portion and the side magnetic portion, respectively.

According to some embodiments, the dampers are fixed under the two ends of the long axis of the voice coil with glue through the first ends, and are fixed under two ends of a long axis of the frame body with glue through the second ends.

Another aspect of the invention provides a damper for a micro-speaker including a first end, a second end, and a cantilever connecting the first end and the second end. A ratio of a length L of the cantilever to a distribution distance D is between 2 and 15. The damper is formed by a flexible circuit board.

According to some embodiments, the damper has a left-right symmetrical structure.

According to some embodiments, the cantilever has no copper layer on a front surface of the damper and a surface of a substrate is exposed.

According to some embodiments, the substrate is made of a polymer material.

According to some embodiments, a voice coil lead is fixed to a welding part of the first end on a front surface of the damper by using electronic spot welding, which is connected to a circuit on a bottom surface of the damper through a via hole, which is electrically connected to a connection terminal on the bottom surface of the second end.

According to some embodiments, an external signal wire is welded to the connection terminal on the bottom surface of the second end.

According to some embodiments, a width of the cantilever is 0.45 mm.

Compared with the prior art, the present invention has the following beneficial effects: by providing elastic dampers formed by flexible circuit boards on the voice coil, sufficient elasticity and damping can be provided to reduce the vibration of the voice coil leads, thereby increasing the rated power, and passing life test under high power operation.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of the appearance of a micro-speaker according to an embodiment of the present invention.

FIG. 2 is an exploded view of the micro-speaker in FIG. 1.

FIG. 3 illustrates a schematic diagram of the front-side layout of the damper.

FIG. 4 illustrates a schematic diagram of the bottom-side layout of the damper.

FIG. 5 shows the length L, width W and distribution distance D of the cantilever of the damper.

### DETAILED DESCRIPTION

In order to make the objectives, technical solutions, and advantages of the embodiments of the present invention clearer, the technical solutions in the embodiments of the present invention will be described clearly and completely in conjunction with the accompanying drawings in the embodiments of the present invention. Obviously, the described embodiments are part of the embodiments of the present invention, but not all of the embodiments. Based on the embodiments of the present invention, all other embodiments obtained by those of ordinary skill in the art without creative work shall fall within the protection scope of the present invention. Therefore, the following detailed description of the embodiments of the present invention provided in the accompanying drawings is not intended to limit the scope of the claimed invention, but merely represents selected embodiments of the present invention.

In the description of the present invention, it should be understood that the terms “center”, “longitudinal”, “transverse”, “length”, “width”, “thickness”, “upper”, “lower”, “front”, “back”, “left”, “Right”, “vertical”, “horizontal”, “top”, “bottom”, “inner”, “outer”, “clockwise”, “counterclockwise” and other directions or the positional relationship are based on the orientation or positional relationship shown in the drawings, and is only for the convenience of describing the present invention and simplifying the description, and does not indicate or imply that the pointed device or element must have a specific orientation, be constructed and operated in a specific orientation, Therefore, it shall not be interpreted as a limitation to the present invention.

In the present invention, unless otherwise clearly defined and specified, the “above” or “below” of the first feature of the second feature may include direct contact between the first and second features, or may include the first and second features not in direct contact but through other features between them. Moreover, “above”, “above” and “above” the second feature of the first feature include the first feature being directly above and obliquely above the second feature, or it simply means that the first feature is higher in level than the second feature. The “below”, “below” and “below” of the second feature of the first feature include the first feature directly below and obliquely below the second feature, or it simply means that the level of the first feature is smaller than the second feature.

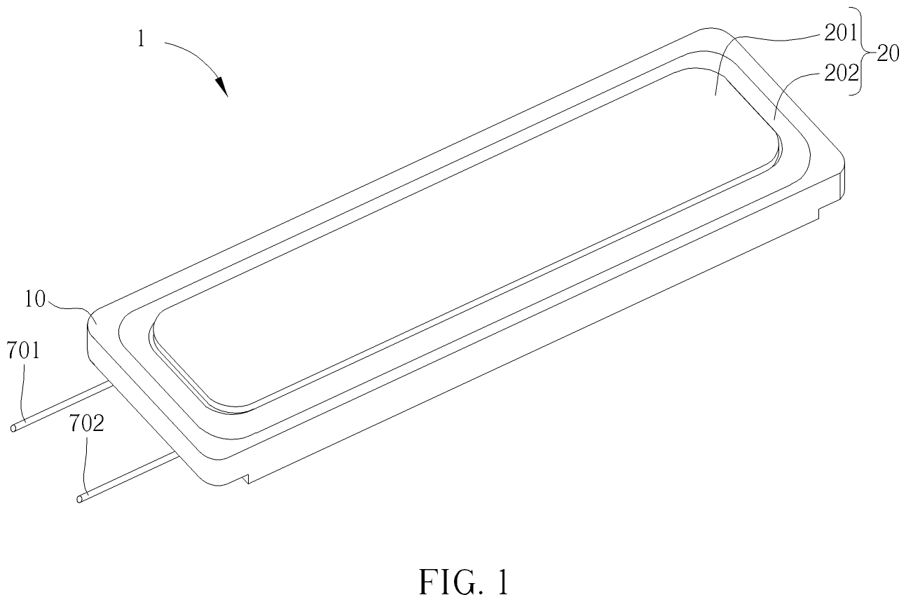

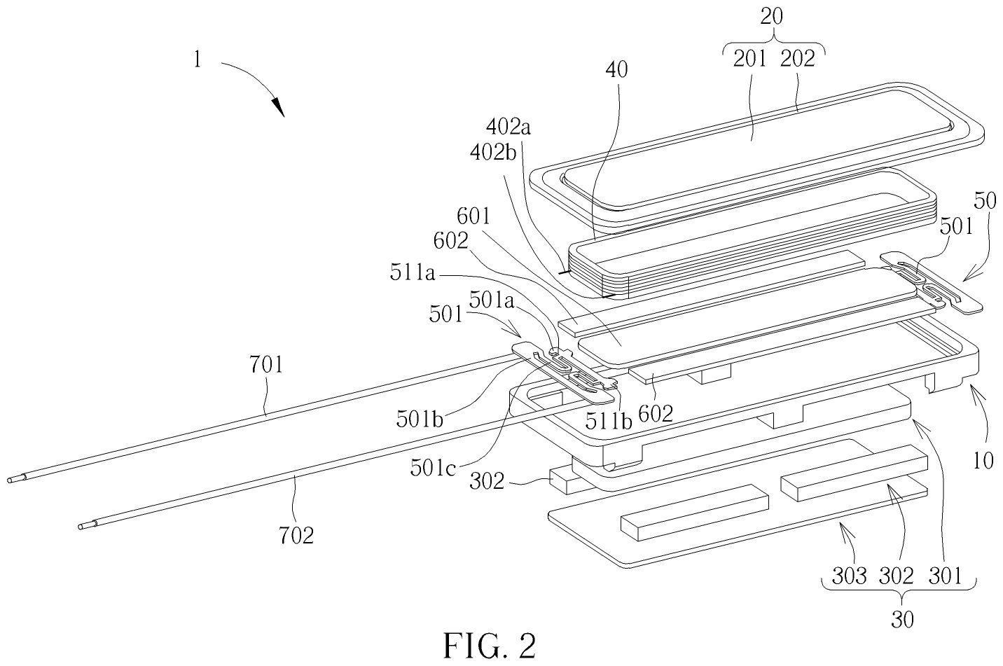

Please refer to FIG. 1 and FIG. 2. FIG. 1 is a schematic diagram of the appearance of a micro-speaker according to an embodiment of the present invention. FIG. 2 is an exploded view of the micro-speaker in FIG. 1. As shown in FIGS. 1 and 2, according to an embodiment of the present invention, the micro-speaker 1 includes a frame body 10 and a drum paper 20 provided on the frame body 10. According to an embodiment of the present invention, the drum paper 20 may include a diaphragm 201 and a surround 202 that encircles the diaphragm 201 and has an arc-shaped or wavy-shaped cross-section. According to an embodiment of the present invention, the diaphragm 201 and the surround 202 may be composed of different materials, but are not limited thereto.

According to an embodiment of the present invention, preferably, the drum paper 20 is flexibly connected to the upper end of the frame body 10. According to an embodiment of the present invention, the diaphragm 201 may be arranged in a slender shape, that is, the size in the length direction is larger than the size in the width direction. According to an embodiment of the present invention, the frame body 10 has an opening that matches the shape of the drum paper 20 and the diaphragm 201, and the diaphragm 201 is connected to the frame body 10 through a ring-shaped surround 202 to seal the opening.

According to an embodiment of the present invention, a magnetic structure 30 is provided in the frame body 10, including a main magnetic portion 301, a side magnetic portion 302 around the outer periphery of the main magnetic portion 301, and yoke 303 located below the main magnetic portion 301 and the side magnetic portion 302. According to an embodiment of the present invention, a gap is provided between the main magnetic portion 301 and the side magnetic portion 302. According to an embodiment of the present invention, washers 601 and 602 for magnetic conduction are provided on the main magnetic portion 301 and the side magnetic portion 302, respectively.

According to an embodiment of the present invention, a voice coil 40 is provided in the frame body 10. According to an embodiment of the present invention, the voice coil 40 is formed by windings of insulated wire and does not require a bobbin. The voice coil 40 is disposed around the outer periphery of the main magnetic portion 301 and installed in the gap in a vertical direction. According to an embodiment of the present invention, the voice coil 40 is arranged in a slender shape, that is, the size in the length direction is larger than the size in the width direction, and the upper end of the voice coil 40 is fixedly connected to the diaphragm 201. Preferably, in an embodiment of the present invention, the center of the voice coil 40 is located on the central axis of the diaphragm 201 in the longitudinal direction. A magnetic field is provided through the magnetic structure to vibrate the voice coil 40 and drive the diaphragm 201 to vibrate and produce sound.

According to an embodiment of the present invention, a voice coil balancing system 50 is additionally provided in the frame body 10, which is mainly composed of two symmetrically arranged dampers 501. According to an embodiment of the present invention, the two dampers 501 are arranged under the two ends of the long axis of the voice coil 40 and fixed with glue. According to an embodiment of the present invention, the damper 501 is composed of a flexible printed circuit (FPC).

According to an embodiment of the present invention, the damper 501 mainly includes a first end 501a, a second end 501b, and a cantilever 501c connecting the first end 501a and the second end 501b. There are hollow parts between the first end 501a, the second end 501b and the cantilever 501c. The damper 501 is fixed under the two ends of the long axis of the voice coil 401 with glue through the first end 501a, and fixed under the two ends of the long axis of the frame body 10 with glue through the second end 501b. The voice coil leads 401a and 401b are respectively fixedly connected to the welding parts 511a and 511b of the first end 501a on the front side of the damper 501 through electronic spot welding, and are electrically connected to the circuit on the bottom surface of the damper 501, which is further electrically connected to the connection terminals on the bottom surface of the second end 501b of the damper 501.

According to an embodiment of the present invention, the connection terminals on the bottom surface of the second end 501b are welded to the external signal wires 701 and 702, respectively, and connected to an external circuit, so as to input the external audio signal through the damper 501, so that the diaphragm 201 vibrates and emits sound.

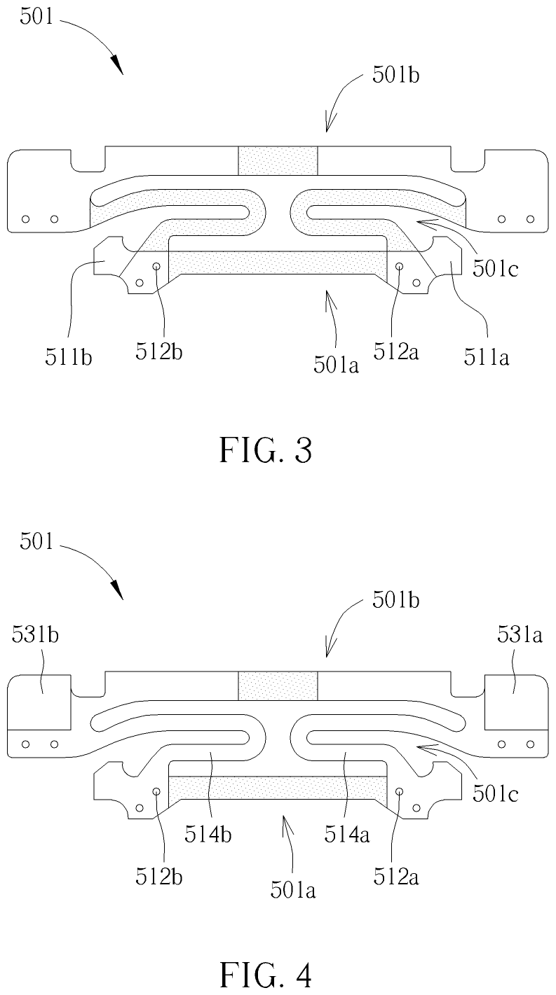

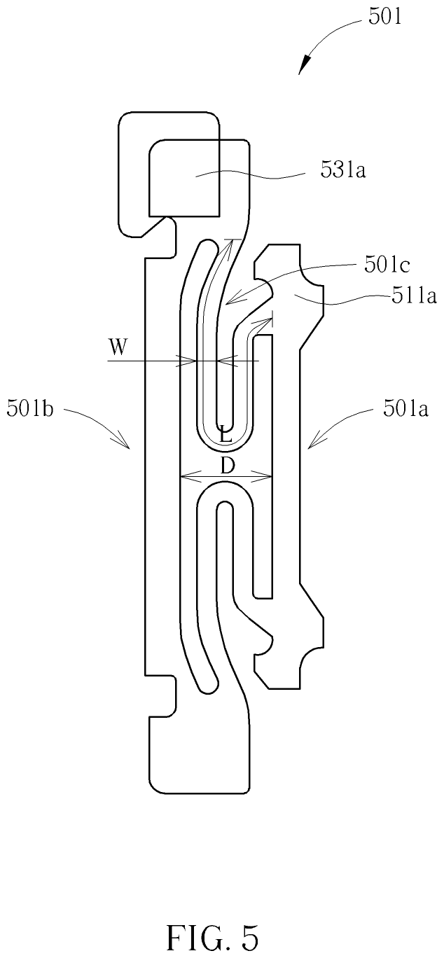

Please refer to FIG. 3 to FIG. 5. FIG. 3 illustrates a schematic diagram of the front-side layout of the damper 501, FIG. 4 illustrates a schematic diagram of the bottom-side layout of the damper 501, and FIG. 5 shows the length L, width W and distribution distance D of the cantilever 501c of the damper 501. As shown in FIG. 3 and FIG. 4, the damper 501 has a left-right symmetrical structure. In order to enable the FPC damper 501 to provide sufficient elasticity and damping, the cantilever 501c has no copper layer on the front surface of the damper 501, and the surface of the substrate is exposed. According to an embodiment of the present invention, the substrate may be composed of a polymer material, such as polyimide resin, but is not limited thereto.

As shown in FIG. 3 and FIG. 4, the voice coil leads 402a and 402b can be fixed to the welding parts 511a and 511b of the first end 501a on the front surface of the damper 501 through electronic spot welding, and electrically connected to the circuit disposed on the bottom surface of the damper 501 through the via holes 512a and 512b, respectively. As previously mentioned, the cantilever 501c has a copper layer only on the bottom surface of the damper 501 (as shown in FIG. 4), which is electrically connected to the connection terminals 531a and 531a on the bottom surface of the second end 501b. The aforementioned external signal wires 701 and 702 are respectively soldered to the connection terminals 531a and 531b on the bottom surface of the second end 501b. According to an embodiment of the present invention, since cantilever 501c has only copper layer, sufficient elasticity and damping can be provided in this way to pass the life test under high power operation.

As shown in FIG. 5, the length L of the cantilever 501c refers to the length from the connection terminal 531a to the welding portion 511a, and the cantilever distribution distance D refers to the area width between the first end 501a and the second end 501b where the serpentine or curved cantilever 501c is distributed. According to an embodiment of the present invention, taking a cantilever width of 0.45 mm as an example, a ratio of the cantilever length L to the cantilever distribution distance D ranging between 2-15 is required.

According the present disclosure, two independent FPC dampers 501 are provided as buffer media, and the voice coil amplitude is borne by the FPC dampers 501 instead of the voice coil leads in the conventional design. The FPC dampers 501 can provide enough elasticity and damping, so that the micro-speakers can also bear the amplitude brought by high power, thereby increasing the rated power (even in the case of reduced size, it can still provide large volume), and pass life test under high-power operation. In addition, the shape, style, and thickness of the two independent FPC dampers 501 can be adjusted according to the vibration mode of the diaphragm 201, thereby making the vibration behavior of the micro-speaker more optimized to provide better sound quality. During the manufacturing process of the two independent FPC dampers 501, they can be connected to the frame body 10 in advance as a semi-finished product, which will simplify the complexity of the assembly and manufacturing process of the micro-speakers.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A micro-speaker, comprising: a frame body, a diaphragm arranged on the frame body, a magnetic structure and a voice coil arranged in the frame body, wherein an upper end of the voice coil is fixed to the diaphragm, the magnetic structure is arranged under the voice coil, and the micro-speaker is characterized in that a voice coil balancing system is provided in the frame body, which is composed of two symmetrically arranged dampers, which are respectively arranged under two opposite ends of a long axis of the voice coil and fixed with glue, wherein each of the dampers is made of a flexible circuit board, including a first end, a second end and a cantilever connecting the first end and the second end, and wherein a ratio of a length L of the cantilever to a distribution distance D of the cantilever is between 2-15.

2. The micro-speaker according to claim 1, wherein the damper has a left-right symmetrical structure.

3. The micro-speaker according to claim 1, wherein the cantilever has no copper layer on a front surface of the damper and a surface of the substrate is exposed.

4. The micro-speaker according to claim 3, wherein the substrate is made of a polymer material.

5. The micro-speaker according to claim 1, wherein a voice coil lead is fixed to a welding part of the first end on a front surface of the damper by using electronic spot welding, which is connected to a circuit on a bottom surface of the damper through a via hole, which is electrically connected to a connection terminal on the bottom surface of the second end.

6. The micro-speaker according to claim 5, wherein an external signal wire is welded to the connection terminal on the bottom surface of the second end.

7. The micro-speaker according to claim 1, wherein a width of the cantilever is 0.45 mm.

8. The micro-speaker according to claim 1, wherein the diaphragm is arranged in a slender shape, and wherein a size of the diaphragm in a length direction is larger than a size in a width direction.

9. The micro-speaker according to claim 8, wherein the frame body has an opening that matches a shape of the diaphragm, and the diaphragm is connected to the frame by a ring-shaped surround to seal the opening.

10. The micro-speaker according to claim 1, wherein the magnetic structure includes a main magnetic portion, a side magnetic portion around an outer periphery of the main magnetic portion, and a yoke under the side magnetic portion and the side magnetic portion, and wherein a gap is located between the main magnetic portion and the side magnetic portion, and the voice coil is disposed around the outer periphery of the main magnetic portion and installed in the gap.

11. The micro-speaker according to claim 10, wherein washers for magnetic conduction are provided on the main magnetic portion and the side magnetic portion, respectively.

12. The micro-speaker according to claim 1, wherein the dampers are fixed under the two ends of the long axis of the voice coil with glue through the first ends, and are fixed under two ends of a long axis of the frame body with glue through the second ends.

13. A damper for a micro-speaker, comprising: a first end, a second end, and a cantilever connecting the first end and the second end, wherein a ratio of a length L of the cantilever to a distribution distance D is between 2 and 15, wherein the damper is formed by a flexible circuit board.

14. The damper for a micro-speaker according to claim 13, wherein the damper has a left-right symmetrical structure.

15. The damper for a micro-speaker according to claim 13, wherein the cantilever has no copper layer on a front surface of the damper and a surface of a substrate is exposed.

16. The damper for micro-speakers according to claim 15, wherein the substrate is made of a polymer material.

17. The damper for a micro-speaker according to claim 13, wherein a voice coil lead is fixed to a welding part of the first end on a front surface of the damper by using electronic spot welding, which is connected to a circuit on a bottom surface of the damper through a via hole, which is electrically connected to a connection terminal on the bottom surface of the second end.

18. The damper for a micro-speaker according to claim 17, wherein an external signal wire is welded to the connection terminal on the bottom surface of the second end.

19. The damper for a micro-speaker according to claim 13, wherein a width of the cantilever is 0.45 mm.
